(19) United States
(12) Patent Application Publication
(10) Pub. No.: US 2025/0142944 A1
(43) Pub. Date: May 1, 2025

(54) METHOD FOR MANUFACTURING A VERTICAL FIELD EFFECT TRANSISTOR STRUCTURE AND CORRESPONDING VERTICAL FIELD EFFECT TRANSISTOR STRUCTURE

(71) Applicant: Robert Bosch GmbH, Stuttgart (DE)

(72) Inventor: Daniel Krebs, Aufhausen (DE)

(21) Appl. No.: 18/910,885

(22) Filed: Oct. 9, 2024

(30) Foreign Application Priority Data
Oct. 30, 2023 (DE) 10 2023 210 709.0

(51) Int. Cl. H01L 29/78; H01L 21/265; H01L 21/266; H01L 29/16; H01L 29/20; H01L 29/66

(52) U.S. Cl. CPC H10D 84/144; H01L 21/26513; H01L 21/266; H10D 30/0297; H10D 30/668; H10D 62/8325; H10D 62/8503

(57) ABSTRACT

A method for manufacturing a vertical field effect transistor structure and a vertical field effect transistor structure. The vertical field effect transistor structure has a semiconductor body having first and second connection zones of a first conductor type, a channel zone of the first conductor type, or of a second conductor type complementary to the first conductor type, arranged between the first and second connection zone, a plurality of trenches extending into the semiconductor body, the trenches reaching from the second connection zone through the channel zone into the first connection zone and forming fins of the channel zone and of the second connection zone, a control electrode arranged in the trenches, the electrode being arranged adjacent to the channel zone and insulated from the semiconductor body, and a breakdown current path connected between the first and second connection zones and in parallel with the channel zone.

### CROSS REFERENCE

The present application claims the benefit under 35 U.S.C. § 119 of German Patent Application No. DE 10 2023 210 709.0 filed on Oct. 30, 2023, which is expressly incorporated herein by reference in its entirety.

### FIELD

The present invention relates to a method for manufacturing a vertical field effect transistor structure and to a corresponding vertical field effect transistor structure.

### BACKGROUND INFORMATION

Power MOSFETs with a vertical channel region (TMOSFETs) are typically used for the application of semiconductors having a wide band gap (e.g., silicon carbide (SiC) or gallium nitride (GaN)) in power electronics.

In the TMOSFET concept, the n+ source region located in a semiconductor material and the p channel region are interrupted by trenches which extend to the n− drift region. Within the trenches is a gate electrode, which is separated from the semiconductor material by a gate oxide and serves for controlling the channel region.

Through a suitable choice of geometry, epitaxy doping, channel doping and screening doping, it is possible to optimize on-resistance, threshold voltage, short-circuit resistance, oxide load and breakdown voltage of such TMOSFETs.

FIG. 3 shows a sectional perspective representation of a vertical field effect transistor structure according to the related art of German Patent No. DE 102 24 201 B4 as the starting point of the present invention.

The semiconductor component shown in FIG. 3 realizes an n-conducting vertical trench MOSFET having a shielding structure arranged at the trenches. The conventional structure is of course also applicable to p-conducting MOSFETs, wherein the dopings explained below would then be swapped.

The semiconductor component comprises a semiconductor body 100 having an n-doped first connection zone 12, 14. This first connection zone 12, 14 is more strongly n-doped in the region of the rear side of the semiconductor body 100 and forms the n+ drain zone 12 of the MOSFET there, whereas a more weakly n-doped n− drift zone 14 adjoins the n+ drain zone 12. The semiconductor body 100 furthermore comprises a p channel zone or body zone 20, which adjoins the n− drift zone 14 and is formed between the n− drift zone 14 and a strongly n-doped second n+ connection zone 30 formed in the region of the front side. The second n+ connection zone 30 forms the source zone of the MOSFET.

Starting from the front side 101 of the semiconductor body 100, multiple trenches 60, two of which are shown in FIG. 3, extend through the n+ source zone 30 and the p body zone 20 to the n− drift zone 14 of the semiconductor body 100.

In the region of the side walls of the trenches 60, control electrodes 40 are arranged in each case, which together form the gate electrode of the MOSFET. These gate electrodes 40 are insulated from the semiconductor body 100 by a gate insulation layer 50 and run in the vertical direction of the semiconductor body from the n+ source zone 30 along the p body zone 20 to the n− drift zone 14 in order to form an electrically conducting channel in the body zone 20 along the side wall of the trench between the n+ source zone 30 and the n− drift zone 14 when a suitable control potential is applied.

The semiconductor component comprises a plurality of similar transistor structures, so-called cells, each having n+ source zones 30, p body zones 20 and gate electrodes 40, wherein a commonality of all the cells in the example is that they have an n− drift zone 14 and an n+ drain zone 12. Here, the n+ source zones 30 of all cells are electrically conductively connected to one another to form a common source zone, and the gate electrodes 40 of all cells are electrically conductively connected to one another to form a common gate electrode.

The semiconductor component shown in FIG. 3 comprises a shielding structure having an electrode 80 formed in each trench 60 and insulated from the respective gate electrode 40 by way of a further insulation layer 70. This electrode 80 extends vertically along the entire length of the trench and, at the bottom of the trench 60, contacts the semiconductor body 100 in the region of the drift zone 14. In this contact region between the electrode 80 and the drift zone 14, a p-doped zone 90 is provided, which is contacted by the electrode 80 and completely covers the electrode in this region. The p-doped zone 90 and the drift zone 14 or the drain zone 12 form a diode, the circuit symbol of which is shown in FIG. 3 and is polarized in the forward direction in the source-drain direction or in the blocking direction in the drain-source direction in the n-conducting MOSFET shown. The breakdown voltage of this diode in the drain-source direction can be adjusted via the doping of the p-doped zone 90. A JFET is thus formed at the p-doped zones and serves to limit the current through the channel region in the event of a short circuit.

The electrode 80 arranged in the trench 60 is shorted to the n+ source zone 30. To this end, the electrode 80 connects directly to the n+ source zone 30 at the side walls of the trench 60 in the upper region of the trench. The electrode 80, which is preferably made of a metal or polysilicon, in particular n-doped or p-doped polysilicon, simultaneously serves as a terminal contact for the n+ source zone 30 so that this electrode 80 can be contacted directly above the trench 60 for the purposes of contacting the n+ source zones 30, whereby it is possible to dispense with contact terminals above the semiconductor regions located between the trenches, these regions being the so-called mesa regions.

The semiconductor component furthermore comprises strongly p-doped p+ body connection regions 22, which, as will be clear from the perspective view in FIG. 3, extend, starting from the p body zone 20, between portions of the n+ source zone 30 to the front side of the semiconductor body 100 and contact the electrode 80 in the upper region of the trench 60 so that the electrode 80 shorts the p body zone 20 and the n+ source zone 30 via the p+ body connection regions 22 in order to avoid parasitic bipolar effects in a conventional manner. The semiconductor component eliminates the need for separate contacts in the semiconductor region formed between the trenches, the so-called mesa region, for shorting the n+ source zone 30 and the p body zone 20.

The narrow p+ body connection regions 22 are sufficient for connecting the p body zone 20 to the electrode 80 so as to achieve the short circuit, making the space required to do so small in the mesa region. The body diode between source 30 and drain 14 created by short-circuiting the n+ source zone 30 and the p body zone 20 has the same polarity as that of the diode of the shielding structure.

The threshold voltage of the shielding structure is set to be less than that of the body diode. When a positive voltage is applied in the source-drain direction, the majority of the current then flows through the diode of the shielding structure, which has a polarity in the forward direction, so that the cross section of the p+ body connection regions 22 through which the p body zone 20 and the n+ source zone 30 are shorted can be small and therefore implemented in a space-saving manner. In this way, the dimensions of this silicon region between the trenches 60 can be reduced in comparison to conventional semiconductor components, which helps to reduce the specific on-resistance of the semiconductor component.

When a positive drain-source voltage is applied, and when a gate potential is applied which is positive relative to a source potential, the conventional semiconductor component works like a conventional MOSFET, the circuit symbol of which is shown in FIG. 3. If the drain-source voltage in a blocking MOSFET exceeds the threshold voltage of the diode formed by the p-doped zone 90 and the drift zone 14, a reverse current flows from a drain connection connected to the drain zone 12 through the drift zone 14, the p-doped zone 90 and the electrode 80 to a source connection connected to the electrode 80. When a voltage is applied in the reverse direction, i.e., when a positive voltage is applied in the source drain direction, this breakdown structure functions like the body diode and assumes the majority of the current then flowing so that the terminal contact for the p body zone 20 can be small and space-saving.

A short circuit can occur in the TMOSFET according to FIG. 3, for example at power-on, without a gate voltage being applied. In this case, a high drain voltage is applied at the semiconductor component and, without suitable countermeasures, a very high short-circuit current can flow, which can lead to the destruction of the component.

Limiting the short-circuit current can be achieved using the JFET formed by the p-doped zones 90, wherein the space charge zones emanating from the p-doped zone 90 approach one another such that a pinch off of the short-circuit current occurs. Thus, in the event of a short circuit, the p-doped zones 90 function as p shielding zones.

A general optimization problem with this TMOSFET is that, in the design of each power MOSFET, a compromise must be found between low on-resistance (i.e., high current at low drain voltages) and low short-circuit current (i.e., low current at high drain voltages).

### SUMMARY

The present invention provides a vertical field effect transistor structure and a method for manufacturing a vertical field effect transistor structure.

Preferred developments and example embodiments of the present invention are disclosed herein.

An underlying idea of the present invention is to implant p shielding implantations in a vertical field effect transistor structure, for example only in every second trench, and still achieve a good compromise of low short-circuit current and low on-resistance.

A p body connection may be designed to be deeper than the p body region so that it extends into the n− drift zone. A PN transition is thus created below the channel and reduces the resistance at high drain voltages, thus helping to reduce the short-circuit current. At high drain voltages, a depletion zone thus forms in the n− drift zone and causes an increase in the resistance of the component. In the event of a short circuit, it is precisely this increase in the resistance that helps to limit the short-circuit current.

Since the short-circuit current is additionally limited by this PN transition in addition to the JFET, which is formed below the fins between two p shielding implantations, it is sufficient according to the present invention to implant only in, for example, every second trench so that a p shielding region is created only under every second trench. The gate electrode in the trenches without p shielding region below the trench bottom is not designed in two parts, because, below the trench, there is no p shielding region that would need to be contacted. The gate electrode in the trenches with p shielding region under the trench bottom can be designed either in two parts (in particular if the p body connection does not reach to the p shielding regions, as in FIG. 1C, in order to contact them) or as an undivided electrode (in particular if the regions are already contacted by a deep p body connection as in FIG. 2B.

The trenches are preferably widened by cyclic oxidation and oxide etching so that the mesas located between the trenches are narrowed to form fins.

According to a preferred development of the present invention, the reverse current path runs inside the trenches, wherein each of the trenches has a respective electrode arranged therein, which electrodes are electrically conductively connected to the second connection zone and are electrically insulated from the control electrode, and a first electrode of the electrodes contacts the doped zone of the second conductor type at the bottom of the first trench of the trenches.

According to a further preferred development of the present invention, the body connection regions of the second conductor type electrically contact the doped zones of the second conductor type, wherein the reverse current path runs through the body connection regions of the second conductor type and through the doped zones of the second conductor type. This has the advantage that complex processing of the connection in the trenches for the purpose of producing the electrodes is not necessary.

According to a further preferred development of the present invention, the first connection zone has a less doped drift region and a more doped drain region of the first conductor type, the doped zones of the second conductor type are arranged in the drift region, and the body connection regions of the second conductor type extend into the drift region.

According to a further preferred development of the present invention, a spreading zone of the first conductor type is provided between the first connection region and the channel zone. This improves current distribution.

According to a further preferred development of the present invention, the semiconductor body is made of silicon carbide or gallium nitride.

### BRIEF DESCRIPTION OF THE DRAWINGS

Further features and advantages of the present invention are explained below on the basis of embodiments with reference to the figures.

FIG. 1A-1H show schematic cross-sectional representations for explaining a method for manufacturing a vertical field effect transistor structure and a corresponding vertical field effect transistor structure according to a first example embodiment of the present invention.

FIGS. 2A and 2B show schematic cross-sectional representations for explaining a method for manufacturing a vertical field effect transistor structure and a corresponding vertical field effect transistor structure according to a second example embodiment of the present invention.

FIG. 3 shows a sectional perspective representation of a vertical field effect transistor structure according to the related art of German Patent No. DE 102 24 201 B4 as the starting point of the present invention.

### DETAILED DESCRIPTION OF EXAMPLE EMBODIMENTS

In the figures, identical reference signs denote identical or functionally identical elements.

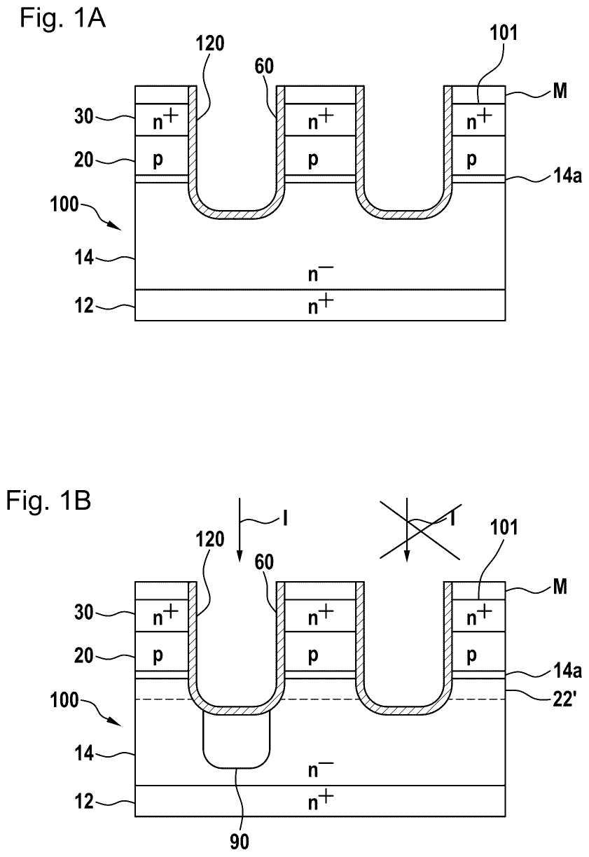

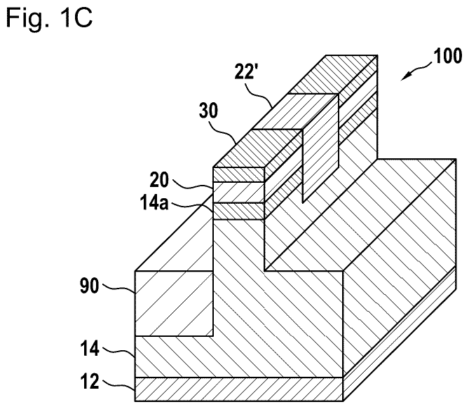

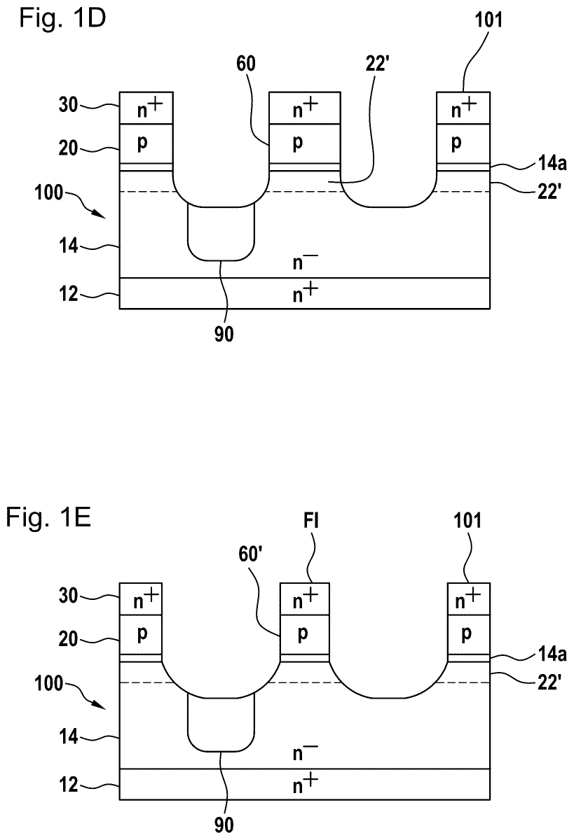

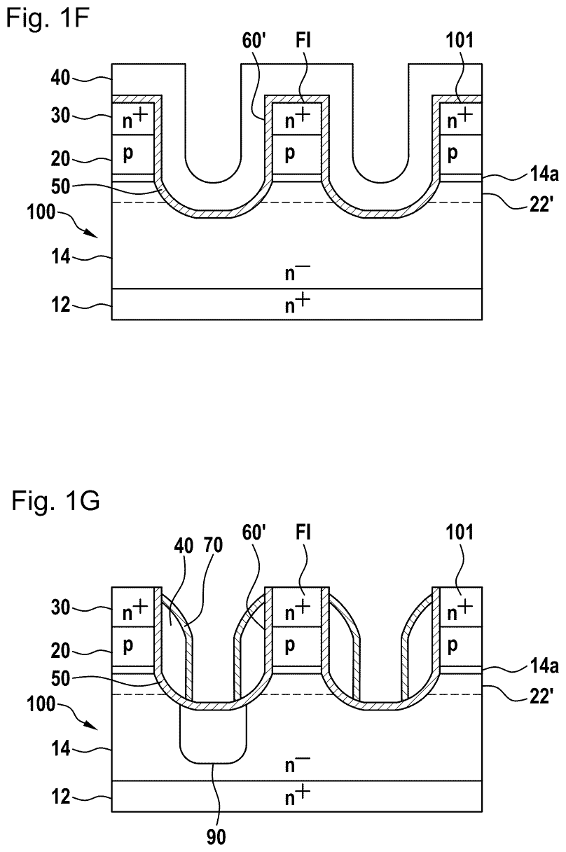

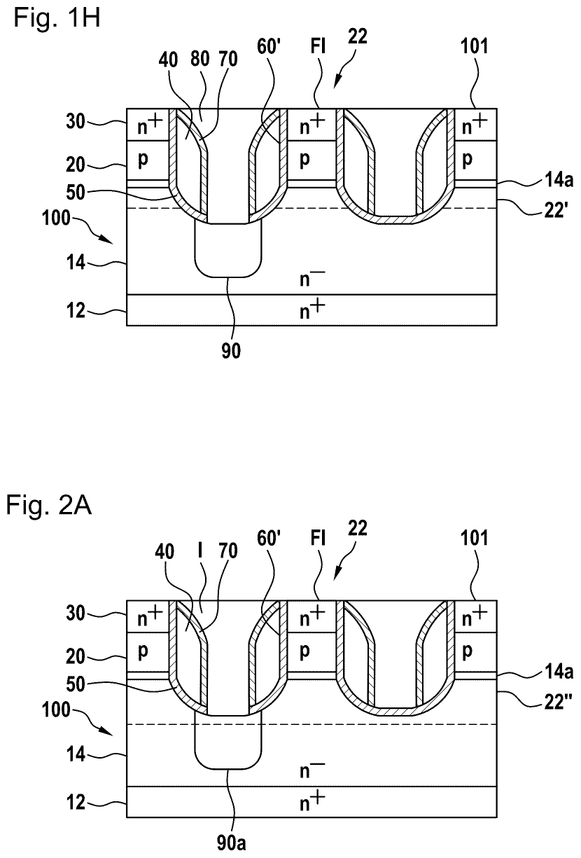

FIGS. 1A-1H show schematic cross-sectional representations for explaining a method for manufacturing a vertical field effect transistor structure and a corresponding vertical field effect transistor structure according to an embodiment of the present invention.

FIG. 1A shows a semiconductor body 100, which has a strongly n-doped zone 12, the later n+ drain zone, in the region of the rear side, a weaker n-doped n− drift zone 14 adjoining the n+ drain zone 12, a p-doped zone 20, the later body zone, adjoining the n− drift zone 14 and, on the front side 101, a strongly n-doped zone, the later n+ source zone 30, adjoining the body zone 20. Optionally, an n-spreading zone 14a can be provided between the n− drift zone 14 and the body zone 20, the spreading zone contributing to better current distribution during operation. The spreading zone 14a may also lie deeper in the n− drift zone 14 or reach deeper into it. In particular, it can reach between the p shielding regions 90.

The process state according to FIG. 1A is achieved by providing the semiconductor body 100 in the form of a semiconductor wafer and subsequently performing conventional epitaxy and implantation steps. A hard mask M is used to etch the trenches 60 into the front side 101 using a trench etching process, and a scatter oxide 120 is subsequently deposited on the walls of the trenches 60. Optionally (not shown), another n-implantation step can be performed in order to generate an n-spreading zone in the n− drift zone 14.

According to FIG. 1B, a p implantation I is subsequently carried out in order to form p-doped zones 90 (p shielding zones) in the n− drift zone 14 below the trenches 60. In the other adjacent trench, no p implantation is carried out. A p implantation may be carried out at regular intervals. For example, a p shielding region may be implanted under every second, third or fourth trench, while p implantation is not carried out in the interjacent trenches. Other patterns of the p shielding regions are also possible, for example two successive trenches with an implanted p shielding region followed by a trench in which no p implantation is carried out. A p implantation can also be carried out only partially in a trench, while partially retaining the n− drift zone 14 in the trench.

In contrast to the conventional structure according to FIG. 3, during the p implantation I, using corresponding openings in the hard mask M, the p body zones 20 can also be contacted in the third dimension via p+ doped regions 22 [symbol] , which alternate with the n+ source zones 30 along n+p fins FI.

The p+ doped regions 22 [symbol] can also be implanted much deeper than the p+ doped regions 22 according to FIG. 3. In particular, in this embodiment, the p+ doped regions 22 [symbol] can extend to the n− drift zone 14 as indicated in FIG. 1B by a dashed line and as illustrated in FIG. 1C in a perspective cutaway sectional view.

By way of an annealing step, the p-doped zones 90 and/or the p+ doped regions 22 [symbol] can be diffused out and activated.

With further reference to FIG. 1D, the hard mask M and the scatter oxide 120 are removed.

Subsequently, according to FIG. 1E, at least the trenches 60 in which an implantation step I according to FIG. 1B has been carried out are widened, wherein the widened trenches 60 [symbol] are delimited laterally by narrowed n+/p mesa regions, which are also called n+/p fins FI. This is carried out by means of cyclic oxidation and oxide etching of the n+/p mesa regions. This step allows undesired p implantation regions which can originate from the implantation step I according to FIG. 1B to be removed from the side walls of the n+/p mesa regions.

FIG. 1F shows the structure following the deposition of the gate insulation layer 50 and a polysilicon layer 40′ from which the gate electrodes 40 are produced on the side walls of the widened trenches 60 [symbol] according to FIG. 1G.

These gate electrodes 40 can be produced by a so-called polyspacer process, for example. For this purpose, using an anisotropic etching process, for example, the polysilicon layer 40 is etched back until the polysilicon layer 40 is removed at the bottom of the trenches 60 [symbol] , from the front side 101 of the semiconductor body 100, and partially from the side walls in the upper region of the widened trenches 60 [symbol] . The gate insulation layer 50 is also removed from the front side 101.

Finally, an insulation layer 70, for example an oxide layer, is generated on the exposed regions of the gate electrodes 60. To this end, either the insulation layer 70 is deposited onto the gate electrodes 40 or the gate electrodes 40 are subjected to an oxidation process. Subsequently, the insulation layer 70 is removed from the front side 101 of the semiconductor body 100 and in the bottom region of the widened trenches 60 [symbol] .

Subsequently, the widened trenches 60 [symbol] are filled with an electrode material, for example a metal or polysilicon, for the purpose of manufacturing the electrodes 80, as shown in FIG. 1H, in order to arrive at the vertical field effect transistor structure according to the embodiment of the present invention. Advantageously, if the electrodes are made of a metal or n-doped silicon, a silicide is applied to the exposed front side 101 of the semiconductor body 100, at least in the region of the p-doped zone, prior to the manufacture of the electrodes 80, in order to obtain good ohmic contact between the electrode 80 and the p-doped zone 90 in order to prevent a pn transition or Schottky contact from developing at this transition. The contacting of the gate electrodes 40 can occur as in conventional trench transistors and is not shown here.

The process sequence described above focuses solely on the processes in the cell field. Other processes outside the cell field, such as edge termination, contact pad lead-outs, etc., must be taken into account. In addition, each step can include multiple sub-steps, which are not specifically listed.

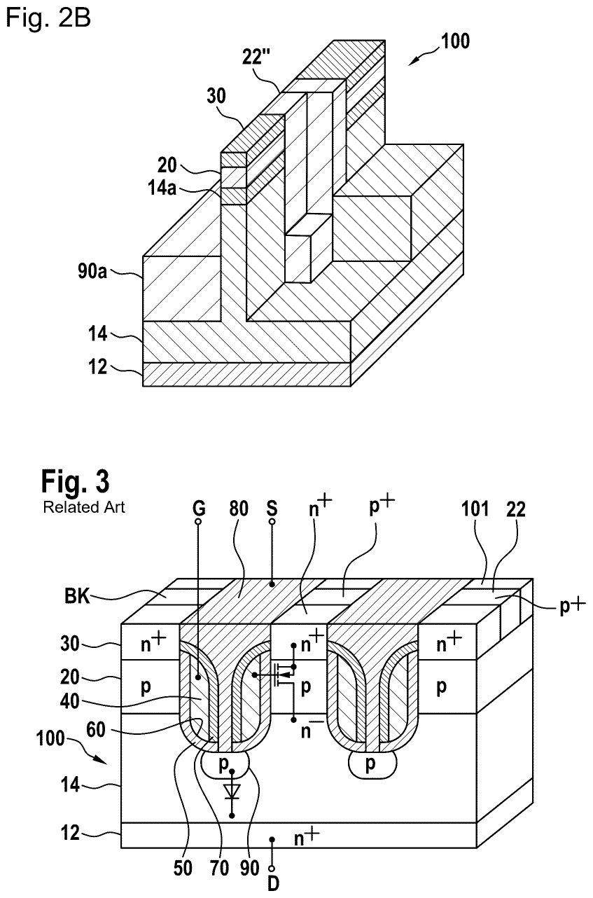

FIGS. 2A and 2B are schematic cross-sectional representations for explaining a method for manufacturing a vertical field effect transistor structure and a corresponding vertical field effect transistor structure according to a second embodiment of the present invention.

As already described with reference to FIG. 1B, a p implantation I has been carried out in order to form a p-doped zone 90a (p shielding zones) in the n− drift zone 14 below the trench 60. The p implantation has been carried out only below the one trench; no p implantation has taken place in the other, adjacent trench. The p implantation I may be carried out as described with reference to FIG. 1B.

FIG. 2A shows the process state analogous to FIG. 1F of the completed vertical field effect transistor structure according to the second embodiment.

In contrast to FIG. 1F, according to FIG. 2A, the p+ doped regions 22 [symbol] [symbol] are implanted even deeper into the n− drift zone 14. This results in the p+ doped regions 22 [symbol] [symbol] and the p-doped zones 90a touching one another and thus being electrically connected to one another. In this way, it becomes unnecessary to electrically connect the p-doped zones 90a (p shielding regions) using the electrodes 80. This is advantageous since complex processing in order to manufacture the electrodes 80 for this connection in the trenches 60 [symbol] is now no longer necessary.

The trenches 60 [symbol] according to FIG. 2A are thus simply filled with an insulation layer I in order to obtain a planar front side 101. Incidentally, for filling and planarization, further layers may also be applied. In particular, in the case of regions 22 [symbol] [symbol] which are implanted deep into the n− drift zone 14 and contact the p-doped zones 90a, it is possible to dispense with bisecting the electrodes 40. In this case (not shown), the trench is completely filled with electrode material and insulated on the surface with an insulation layer I.

FIG. 2B shows, in a perspective cutaway sectional view, the process state analogous to FIG. 1C for the purpose of clarifying that the p+ doped regions 22 [symbol] [symbol] and the p-doped zones 90a contact one another.

Although the present invention has been described with reference to preferred exemplary embodiments, it is not limited thereto. In particular, the materials and topologies mentioned are only exemplary and not limited to the examples explained. The geometries shown are also only exemplary and can be varied in any way as needed.

In the embodiments described above, although the p+ doped regions and the p-doped zones were formed in a common implantation step, it is also possible to use two separate implantation steps for this purpose.

What is claimed is:

1. A vertical field effect transistor structure, comprising:
a semiconductor body having a first connection zone and a second connection zone each being of a first conductor type;
a channel zone of the first conductor type, or of a second conductor type complementary to the first conductor type, arranged between the first and second connection zones;
a plurality of trenches extending into the semiconductor body, the trenches reaching from the second connection zone through the channel zone into the first connection zone and forming fins of the channel zone and of the second connection zone;
a control electrode arranged in the trenches, the electrode being adjacent to the channel zone and insulated from the semiconductor body;
a reverse current path connected between the first and second connection zones and in parallel with the channel zone, the reverse current path including at least one pn transition and being configured to conduct when a threshold voltage applied between the first and second connection zones is reached;
wherein the semiconductor body includes a doped zone of the second conductor type in the first connection zone below a first trench of the trenches, and the first connection zone below a second trench of the trenches does not have a doped zone of the second conductor type;
wherein the fins include body connection regions of the second conductor type, which electrically contact the channel zone and the second connection zone; and
wherein the body connection regions of the second conductor type extend into a drift zone.

2. The vertical field effect transistor structure according to claim 1, wherein the reverse current path runs within the trenches, wherein each trench of the trenches has a respective electrode arranged in trench, the respective electrodes are electrically conductively connected to the second connection zone and are electrically insulated from the control electrode, and a first electrode of the electrodes contacts the doped zone of the second conductor type at a bottom of the first trench of the trenches.

3. The vertical field effect transistor structure according to claim 1, wherein the body connection regions of the second conductor type electrically contact the doped zone of the second conductor type, and wherein a breakdown current path runs through the body connection regions of the second conductor type and through the doped zone of the second conductor type.

4. The vertical field effect transistor structure according to claim 1, wherein the first connection zone includes a lower doped drift region and a higher doped drain region of the first conductor type, the doped zone of the second conductor type being arranged in the drift region, and wherein the body connection regions of the second conductor type extend into the drift region.

5. The vertical field effect transistor structure according to claim 1, wherein a spreading zone of the first conductor type is provided between the first connection region and the channel zone.

6. The vertical field effect transistor structure according to claim 1, wherein the semiconductor body is made of silicon carbide (SiC) or gallium nitride (GaN).

7. A method for manufacturing a vertical field effect transistor, the method comprising the following steps:
providing a semiconductor body having a first connection zone and a second connection zone, each being of a first conductor type, and a channel zone of the first conductor type or of a second conductor type complementary to the first conductor type, arranged between the first and second connection zone;
forming a plurality of trenches extending into the semiconductor body, the trenches reaching from the second connection zone through the channel zone into the first connection zone and forming fins of the channel zone and of the second connection zone;
forming a control electrode arranged in the trenches, the electrode being adjacent to the channel zone and insulated from the semiconductor body;
forming a reverse current path connected between the first and second connection zones and in parallel with the channel zone, the current path comprising at least one pn transition and being designed to conduct when a threshold voltage applied between the first and second connection zones is reached;
forming a doped zone of the second conductor type in the first connection zone below a first trench of the trenches, and the first connection zone below a second trench of the trenches does not have a doped zone of the second conductor type; and
forming body connection regions of the second conductor type in the fins, the body connection regions electrically contacting the channel zone and the second connection zone;
wherein the body connection regions of the second conductor type are formed such that they extend into a drift zone.

8. The method according to claim 7, wherein the doped zone of the second conductor type and the body connection regions of the second conductor type are formed in a common implantation step.

9. The method according to claim 7, wherein the reverse current path runs inside the trenches, wherein each trench of the trenches has a respective electrode arranged in the trench, the respective electrodes being electrically conductively connected to the second connection zone and are electrically insulated from the control electrode, and a first electrode of the electrodes contacts the doped zone of the second conductor type at a bottom of the first trench of the trenches.

10. The method according to claim 7, wherein the body connection regions of the second conductor type are formed such that the body connection regions electrically contact the doped zone of the second conductor type, and wherein a breakdown current path runs through the body connection regions of the second conductor type and through the doped zone of the second conductor type.

11. The method according to claim 7, wherein the first connection zone includes a lower doped drift region and a higher doped drain region of the first conductor type, the doped zone of the second conductor type being arranged in the drift region, and wherein the body connection regions of the second conductor type extend into the drift region.

12. The method according to claim 7, wherein a spreading zone of the first conductor type is provided between the first connection region and the channel zone.
